(19) United States
(12) Patent Application Publication
(10) Pub. No.: US 2025/0212516 A1
(43) Pub. Date: Jun. 26, 2025

(54) THIN FILM TRANSISTOR SUBSTRATE AND DISPLAY DEVICE USING THE SAME

(71) Applicant: LG Display Co., Ltd., Seoul (KR)

(72) Inventors: Yubeen LIM, Paju-si (KR); Soyang CHOI, Paju-si (KR); Youngjin YI, Paju-si (KR); HyeJi JEON, Paju-si (KR)

(73) Assignee: LG Display Co., Ltd., Seoul (KR)

(21) Appl. No.: 18/913,532

(22) Filed: Oct. 11, 2024

(30) Foreign Application Priority Data
Dec. 26, 2023 (KR) 10-2023-0191622

(51) Int. Cl. H01L 27/12; H10K 59/121

(52) U.S. Cl. CPC H10D 86/60; H10D 86/421; H10D 86/451; H10K 59/1213; H10D 86/021

(57) ABSTRACT

A thin film transistor substrate and a display device including the same. The thin film transistor substrate includes a substrate, a buffer layer having a buffer groove disposed on the substrate, wherein the buffer groove includes an inclined surface, an active layer disposed on the buffer layer, and a gate electrode disposed on the active layer, wherein the active layer is disposed to be stepped on the buffer groove, and one end of the gate electrode overlaps the inclined surface of the buffer groove.

### CROSS-REFERENCE TO RELATED APPLICATIONS

This application claims the benefit of and the priority to the Korean Patent Application No. 10-2023-0191622 filed on Dec. 26, 2023, which is hereby incorporated by reference as if fully set forth herein.

### BACKGROUND

### Technical Field

The present disclosure relates to a thin film transistor substrate and a display device using the same.

### Description of the Related Art

Since thin film transistors can be manufactured on glass or plastic substrates, they are widely used as switching or driving elements of display devices such as liquid crystal display devices or organic light emitting devices.

Various types of thin film transistors, such as a driving thin film transistor for emitting individual pixels, a switching thin film transistor for adjusting the amount of voltage applied to the driving thin film transistor, a Logic-GIP thin film transistor for controlling a thin film transistor provided in the display area, and a Buffer-GIP thin film transistor for controlling the overall power supply, may be used for the display panel for driving the organic light emitting device (OLED).

In order to implement a device having high mobility, in a thin film transistor having a top gate structure, a process of conducting an oxide semiconductor layer may be performed by using a gate electrode as a mask. However, in the process of conducting the oxide semiconductor layer, a region to be conductive may be excessively penetrated, and thus the channel region may be formed to be smaller than the set region, and accordingly, the channel length may be reduced and the threshold voltage Vth may be shifted in the negative (−) direction. In particular, when the width of the oxide semiconductor layer is large, the degree of penetration of the region to be conductive may increase, and thus the channel length may be further shortened.

When the threshold voltage Vth is shifted in the negative (−) direction, a leakage current may occur in an initial image. As a result, a display panel including a thin film transistor may be driven poorly due to the leakage current, and a problem in which power consumption of the panel increases may occur.

### SUMMARY

The present disclosure has been made in view of the above problems, and it is an object of the present disclosure to provide a thin film transistor substrate wherein an active layer is disposed on a buffer groove provided in a buffer layer, thereby preventing deep penetration of oxygen vacancies diffused through a conducting process into the channel of the active layer, thus preventing a negative shift of threshold voltage Vth of the thin film transistor, and a display device including the same.

To achieve these and other advantages and in accordance with objects of the disclosure, as embodied and broadly described herein, a thin film transistor substrate comprises a substrate, a buffer layer having a buffer groove disposed on the substrate, wherein the buffer groove includes an inclined surface, an active layer disposed on the buffer layer, and a gate electrode disposed on the active layer, wherein the active layer is disposed to be stepped on the buffer groove, and one end of the gate electrode overlaps the inclined surface of the buffer groove.

In some example embodiments, one end of the gate electrode may overlap a portion of the active layer disposed on the inclined surface of the buffer groove.

In some example embodiments, the thin film transistor substrate may further comprise a gate insulating layer disposed between the active layer and the gate electrode, wherein the gate insulating layer overlaps the buffer groove, and one end of the gate insulating layer corresponds to one end of the gate electrode.

In some example embodiments, the thin film transistor substrate may further comprise a gate insulating layer disposed between the active layer and the gate electrode, wherein the gate insulating layer overlaps the buffer groove, and one end of the gate insulating layer is disposed between one end of the active layer and one end of the gate electrode.

In some example embodiments, the gate insulating layer may have a first width, the gate electrode may have a second width, the active layer has a first length, and the first width of the gate insulating layer may be larger than the second width of the gate electrode and smaller than the first length of the active layer.

In some example embodiments, the active layer may include a channel part, a connection part disposed on one side of the channel part, and a diffusion part disposed between the channel part and the connection part, and the channel part may include a first region in contact with a bottom surface of the buffer groove and a second region in contact with the inclined surface of the buffer groove.

In some example embodiments, one end of the second region of the channel part may be disposed in the inclined surface.

In some example embodiments, one end of the second region of the channel part may correspond to one end of the gate electrode.

In some example embodiments, one end of the diffusion part may be disposed on the inclined surface of the buffer groove.

In some example embodiments, another end of the diffusion part may correspond to one end of the gate electrode.

In some example embodiments, another end of the diffusion part may be disposed between one end of the gate electrode and one end of the active layer.

In some example embodiments, the active layer may include a channel part, a connection part disposed on one side of the channel part, and a diffusion part disposed between the channel part and the connection part, one end of the channel part may be disposed on a bottom surface of the buffer groove, and one end of the diffusion part is disposed on the inclined surface of the buffer groove, and one end of the channel part and one end of the diffusion part may be in contact with each other at a boundary between the bottom surface of the buffer groove and the inclined surface of the buffer groove.

In some example embodiments, the buffer groove may further include a bottom surface connected to the inclined surface, and an angle formed between the bottom surface and the inclined surface may be equal to 30 degrees or more and equal to 45 degrees or less.

In some example embodiments, the buffer groove may further include a bottom surface connected to the inclined surface, and a depth of the bottom surface of the buffer groove may be equal to 1.41 μm or more and equal to 2 μm or less.

In another aspect of the present disclosure, a thin film transistor substrate comprises a substrate, a buffer layer having a buffer groove disposed on the substrate, an active layer disposed on the buffer layer, and a gate electrode disposed on the active layer, wherein the buffer groove includes a bottom surface and an inclined surface connected to the bottom surface, the active layer includes a channel part, a connection part disposed on one side of the channel part, and a diffusion part disposed between the channel part and the connection part, and the channel part overlaps the bottom surface and the inclined surface, and one end of the channel part is disposed on the inclined surface of the buffer groove.

In some example embodiments, a width of the bottom surface of the buffer groove may be smaller than a width of the gate electrode, and a width of the entire bottom surface and inclined surface of the buffer groove is larger than the width of the gate electrode.

In some example embodiments, the thin film transistor substrate may further comprise a gate insulating layer disposed between the active layer and the gate electrode, wherein an entire area of the diffusion part may overlap the gate insulating layer.

In some example embodiments, a portion of the diffusion part may not overlap the gate electrode.

In some example embodiments, one end of the channel part may correspond to one end of the gate electrode.

In yet another aspect of the present disclosure, a display device includes a thin film transistor substrate comprising a substrate, a buffer layer disposed on the substrate and having a buffer groove, an active layer disposed on the buffer layer, and a gate electrode disposed on the active layer, wherein the active layer is disposed to be stepped on the buffer groove, and one end of the gate electrode overlaps an inclined surface disposed in the buffer groove.

It is to be understood that both the foregoing general description and the following detailed description of the present disclosure are by way of example and are intended to provide further explanation of the disclosure.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principles of the disclosure.

FIG. 1 is a plan view of a thin film transistor substrate according to an embodiment of the present disclosure.

FIG. 2A is a cross-sectional view of a thin film transistor substrate according to an embodiment of the present disclosure. In this case, FIG. 2A corresponds to the cross-sectional view I-I′ of FIG. 1.

FIG. 2B is a cross-sectional view of a thin film transistor substrate according to another embodiment of the present disclosure. In this case, FIG. 2B corresponds to the cross-sectional view I-I′ of FIG. 1.

FIGS. 3A and 3B are schematic diagrams illustrating a cross section of a thin film transistor substrate according to an embodiment of the present disclosure and a thin film transistor substrate according to a comparative example, respectively.

FIG. 3C is a carrier concentration graph according to a distance to a diffusion part of a thin film transistor substrate according to an embodiment of the present disclosure and a thin film transistor substrate according to a comparative example.

FIGS. 4A to 4E are cross-sectional views of a process of manufacturing a thin film transistor substrate according to an embodiment of the present disclosure.

FIG. 5 is a cross-sectional view of a thin film transistor substrate according to another embodiment of the present disclosure. In this case, FIG. 5 corresponds to the cross-sectional view I-I′ of FIG. 1.

FIGS. 6A to 6F are cross-sectional views of a process of manufacturing a thin film transistor substrate according to another embodiment of the present disclosure.

FIG. 7 is a cross-sectional view of a display device including a thin film transistor substrate according to an embodiment of the present disclosure.

FIG. 8 is a schematic view of a display device according to an embodiment of the present disclosure.

FIG. 9 is a circuit diagram of a pixel included in a display device according to an embodiment of the present disclosure.

### DETAILED DESCRIPTION

Advantages and features of the present disclosure, and implementation methods thereof will be clarified through the following embodiments, described with reference to the accompanying drawings. The present disclosure may, however, be embodied in different forms and should not be construed as being limited to the embodiments set forth herein. Rather, these embodiments are provided so that this disclosure will be thorough and complete, and will fully convey the scope of the present disclosure to those skilled in the art. Further, the present disclosure is only defined by the scope of the claims.

The shapes, sizes, ratios, angles, and numbers disclosed in the drawings for describing embodiments of the present disclosure are merely examples, and thus the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In the case in which “comprise,” “have,” and “include” described in the present specification are used, another part may also be present unless “only” is used. The terms in a singular form may include plural forms unless noted to the contrary.

In construing an element, the element is construed as including an error region although there is no explicit description thereof.

In describing a positional relationship, for example, when the positional order is described as “on,” “above,” “below,” “beneath”, and “next,” the case of no contact therebetween may be included, unless “just” or “direct” is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other, and may be variously inter-operated with each other and driven technically The embodiments of the present disclosure may be carried out independently from each other, or may be carried out together in a co-dependent relationship.

In the drawings, the same or similar elements are denoted by the same reference numerals even though they are depicted in different drawings.

In the embodiments of the present disclosure, a source electrode and a drain electrode are distinguished from each other, for convenience of explanation. However, the source electrode and the drain electrode are used interchangeably. Thus, the source electrode may be the drain electrode, and the drain electrode may be the source electrode. Also, the source electrode in any one embodiment of the present disclosure may be the drain electrode in another embodiment of the present disclosure, and the drain electrode in any one embodiment of the present disclosure may be the source electrode in another embodiment of the present disclosure.

In one or more embodiments of the present disclosure, for convenience of explanation, a source region is distinguished from a source electrode, and a drain region is distinguished from a drain electrode. However, embodiments of the present disclosure are not limited to this structure. For example, a source region may be a source electrode, and a drain region may be a drain electrode. Also, a source region may be a drain electrode, and a drain region may be a source electrode.

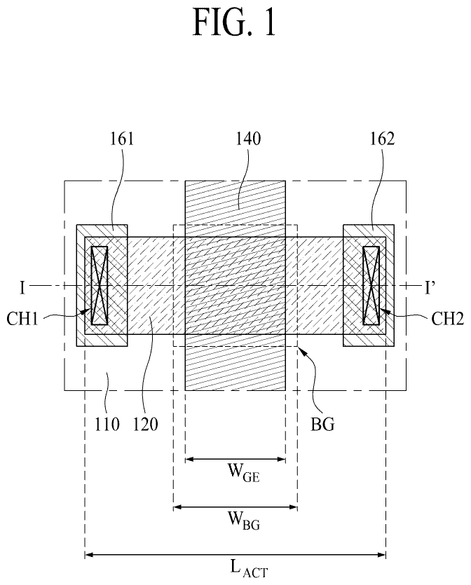

FIG. 1 is a plan view of a thin film transistor substrate according to an embodiment of the present disclosure.

As shown in FIG. 1, a thin film transistor substrate according to an embodiment of the present disclosure may include a buffer layer 110, an active layer 120, a gate electrode 140, a source electrode 161, and a drain electrode 162.

The active layer 120 may extend in a first direction, for example, in a horizontal direction. The source electrode 161 may be provided on one side of the active layer 120, for example, on the left side, and the drain electrode 162 may be provided on another side, for example, on the right side, of the active layer 120.

The gate electrode 140 may extend in a second direction, for example, a vertical direction. In this case, the second direction may correspond to a direction perpendicular to the first direction. The gate electrode 140 overlaps the active layer 120.

The source electrode 161 may be electrically connected to one side of the active layer 120 through a first contact hole CH1, and the drain electrode 162 may be electrically connected to another side of the active layer 120 through a second contact hole CH2.

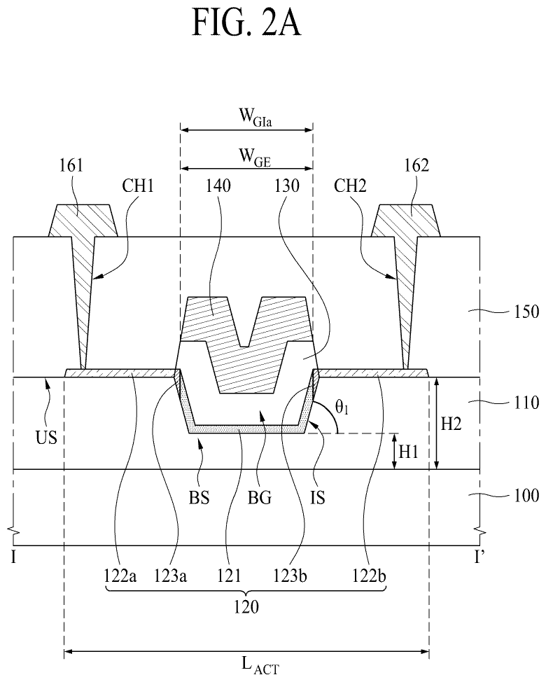

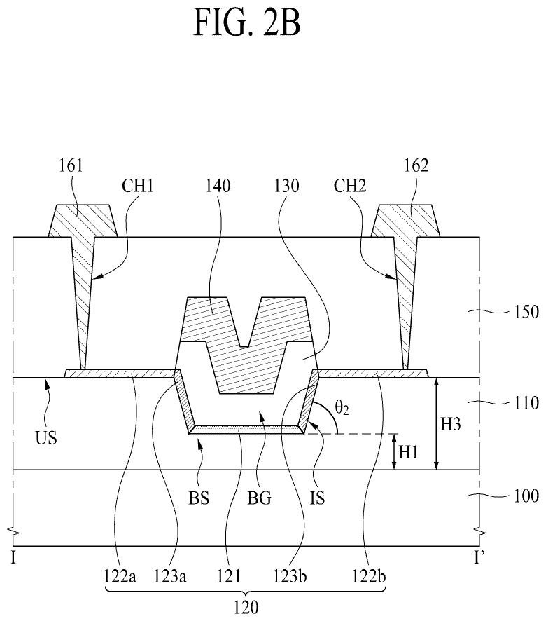

According to an embodiment of the present disclosure, the buffer layer 110 may be formed on an entire surface of the thin film transistor substrate according to an embodiment of the present disclosure to overlap the active layer 120, the gate electrode 140, the source electrode 161, and the drain electrode 162. In this case, since the buffer groove BG is provided in the buffer layer 110, a length of the channel part provided in the active layer 120 may be prevented from being excessively shortened, and this will be described in detail with reference to FIG. 2A below.

The buffer groove BG may overlap the active layer 120 and the gate electrode 140 in a region where the active layer 120 and the gate electrode 140 overlap each other. In this case, the buffer groove BG may have a first width W_{BG} in the horizontal direction, the gate electrode 140 may have a second width W_{GE} in the horizontal direction, and the active layer 120 may have a first length L_{ACT} in the horizontal direction.

According to an embodiment of the present disclosure, the first width W_{BG} of the buffer groove BG may be formed to be greater than the second width W_{GE} of the gate electrode 140, and the first width W_{BG} of the buffer groove BG may be formed to be smaller than the first length L_{ACT} of the active layer 120.

FIG. 2A is a cross-sectional view of a thin film transistor substrate according to an embodiment of the present disclosure. In this case, FIG. 2A corresponds to the cross-sectional view I-I′ of FIG. 1.

As shown in FIG. 2A, a thin film transistor substrate according to an embodiment of the present disclosure may include a substrate 100, a buffer layer 110, an active layer 120, a gate insulating layer 130, a gate electrode 140, an interlayer insulating layer 150, a source electrode 161, and a drain electrode 162.

The substrate 100 may be made of glass or plastic. In particular, the substrate 100 may be made of transparent plastic having flexible characteristics, for example, polyimide. When the polyimide is used as the substrate 100, considering that a high-temperature deposition process is performed on the substrate 100, heat-resistant polyimide capable of withstanding high temperature may be used.

The buffer layer 110 may be formed on the substrate 100. The buffer layer 110 may protect the active layer 120 by blocking air and moisture. The buffer layer 110 may be made of an inorganic insulating material such as silicon oxide, silicon nitride, or metal oxide, but is not limited thereto and may be made of an organic insulating material.

According to an embodiment of the present disclosure, the buffer layer 110 may be provided with a buffer groove BG concavely formed from the upper surface US of the buffer layer 110. The buffer groove BG is formed by removing a partial region of the upper surface of the buffer layer 110.

The buffer groove BG includes a bottom surface BS provided at the deepest portion from the upper surface US of the buffer layer 110, and an inclined surface IS connected to the bottom surface BS and forming a first angle θ₁ with the bottom surface.

The first angle θ1 formed by the bottom surface BS of the buffer groove BG and the inclined surface IS may be equal to 30 degrees or more and equal to 45 degrees or less. When the first angle θ₁ formed by the bottom surface BS and the inclined surface IS is less than 30 degrees, the length of the channel part 121 may be excessively shortened by oxygen vacancy diffused from the first connection part 122a or the second connection part 122b, and when the first angle θ1 formed by the bottom surface BS and the inclined surface IS exceeds 45 degrees, the thickness of the active layer 120 deposited on the inclined surface IS and the thickness of the active layer 120 deposited on the bottom surface BS and the upper surface US may become different from each other, causing a problem of uneven characteristics of devices.

By adjusting a first height H1 of the bottom surface BS of the buffer groove BG and a second height H2 of the upper surface US of the buffer layer 110, a first angle θ1 of the inclined surface IS may be controlled. In this case, each of the first height H1 and the second height H2 may be defined as a distance from a lower surface of the buffer layer 110 to a bottom surface BS of the buffer groove BG or a distance from a lower surface of the buffer layer 110 to an upper surface US of the buffer layer 110.

According to an embodiment of the present disclosure, the depth H2-H1 of the bottom surface BS of the buffer groove BG may be equal to 1.41 μm or more and equal to 2 μm or less. When the depth H2-H1 of the bottom surface BS of the buffer groove BG is less than 1.41 μm, the length of the channel part 121 may be excessively shortened by oxygen vacancy diffused from the first connection part 122a or the second connection part 122b, and when the depth H2-H1 of the bottom surface BS of the buffer groove BG exceeds 2 μm, the thicknesses of the active layer 120 deposited on the inclined surface IS and the thickness of the active layer 120 deposited on the bottom surface BS and the upper surface US may become different from each other, thereby causing a problem of uneven characteristics of devices.

The active layer 120 may be provided on the buffer layer 110 to overlap the buffer groove BG. Specifically, the active layer 120 may be provided on a portion of an upper surface of the buffer layer 110, an inclined surface IS of the buffer groove BG, and a bottom surface BS of the buffer groove BG. The active layer 120 may be provided to be stepped on the buffer groove BG. In this case, the active layer 120 may have a first length L_{ACT} in a horizontal direction.

The active layer 120 may include a semiconductor material, for example, an oxide semiconductor material. The oxide semiconductor material may include at least one of, for example, an IZO (InZnO)-based oxide semiconductor material, an IGO (InGaO)-based oxide semiconductor material, an ITO (InSnO)-based oxide semiconductor material, an IGZO (InGaZnO)-based oxide semiconductor material, an IGZTO (InGaZnSnO)-based oxide semiconductor material, a GZTO (GaZnSnO)-based oxide semiconductor material, a GZO (GaZnO)-based oxide semiconductor material, an ITZO (InSnZnO)-based oxide semiconductor material, and a FIZO (FeInZnO)-based oxide semiconductor material.

The active layer 120 may include a channel part 121, a first connection part 122a, a second connection part 122b, a first diffusion part 123a, and a second diffusion part 123b. In this case, the first connection part 122a is provided on one side of the channel part 121, for example, on the left side, and the second connection part 122b is provided on another side, for example, on the right side, of the channel part 121, and the first diffusion part 123a is provided between the channel part 121 and the first connection part 122a, and the second diffusion part 123b may be provided between the channel part 121 and the second connection part 122b.

The channel part 121 is provided inside the buffer groove BG. Specifically, the central portion of the channel part 121 may be provided on the bottom surface BS of the buffer groove BG, and one end and another end of the channel part 121 may be provided on the inclined surface IS of the buffer groove BG.

The channel part 121 includes a first region which is connected to the bottom surface BS and a second region which is connected to the first region and is in contact with the inclined surface IS. In this case, the first region and the second region may form a first angle θ₁ like the bottom surface BS of the buffer groove BG and the inclined surface IS.

The channel part 121 overlaps the gate electrode 140. According to an embodiment of the present disclosure, one end of the channel part 121, for example, a left end, corresponds to one end of the gate electrode 140, for example, a left end, and another end of the channel part 121, for example, a right end, may correspond to another end of the gate electrode 140. However, the present disclosure is not limited thereto.

The first connection part 122a and the second connection part 122b may have conductive characteristics, for example, by a conducting process of performing plasma treatment on a semiconductor material using the gate electrode 140 as a mask. For example, in the first connection part 122a and the second connection part 122b, a partial region of the active layer 120 may be conductive in the process of patterning the gate insulating layer 130 provided on the active layer 120. The gate insulating layer 130 may be formed on the entire surface of the active layer 120 and then etched by plasma to form a pattern. In this case, a partial region of the active layer 120 exposed while a portion of the gate insulating layer 130 formed on the entire surface is etched in the process of patterning the gate insulating layer 130 may be conductive to form the first connection part 122a and the second connection part 122b.

The conducting process may be defined as a process of imparting conductive characteristics to an oxide semiconductor material. The oxide semiconductor material in which the conducting process has been performed may have conductive characteristics. The conducting process may include, for example, a plasma process in which a plasma is applied to become a conductor, but is not limited thereto. More specifically, when a plasma is applied to an oxide semiconductor material, oxygen contained in the oxide semiconductor is discharged and oxygen vacancies are formed, and electrons move through the oxygen vacancy. As a result, the oxide semiconductor material has conductive characteristics due to the oxygen vacancy. When plasma is used for the conducting process, the plasma may contain, for example, fluorine F. Specifically, the plasma containing fluorine F may be, for example, sulfur hexafluoride SF₆ and nitrogen trifluoride NF₃. However, the plasma for conducting the first connection part 122a and the second connection part 122b is not limited thereto, and may include various materials known in the art.

Through the conducting process, a partial region of the active layer 120, for example, the first connection part 122a and the second connection part 122b may be conductive to have conductive characteristics. Therefore, the first connection part 122a and the second connection part 122b may have better conductivity than the channel part 121, and each of them may serve as a wiring or source/drain electrode.

The first diffusion part 123a and the second diffusion part 123b may be formed during the formation of the first connection part 122a or the second connection part 122b, respectively. Specifically, oxygen vacancy formed in the first connection part 122a or the second connection part 122b may be diffused toward the center of the channel part 121 through the conducting process, and the first diffusion part 123a and the second diffusion part 123b are formed by the oxygen vacancy diffused toward the center of the channel part 121.

For example, as oxygen vacancy formed in the first connection part 122a is diffused in a direction of the channel part 121, the first diffusion part 123a may be formed. Likewise, as oxygen vacancy formed in the second connection part 122b is diffused, the second diffusion part 123b may be formed.

Since the first diffusion part 123a and the second diffusion part 123b are conductive by oxygen vacancy diffused from the first connection part 122a and the second connection part 122b, conductivity characteristics are relatively lower than those of the first connection part 122a and the second connection part 122b, but conductivity characteristics are relatively higher than those of the channel part 121.

According to an embodiment of the present disclosure, the first diffusion part 123a and the second diffusion part 123b may be disposed within the inclined surface IS of the buffer groove BG. Specifically, any one of one end and another end of the first diffusion part 123a or the second diffusion part 123b may be disposed within the inclined surface IS. By forming in this way, even if oxygen vacancy is diffused from the first connection part 122a or the second connection part 122b, the length of the designed channel part 121 may be secured. Since the length of the channel part 121 may be secured as designed, a thin film transistor substrate having a short channel may be realized without a threshold voltage Vth being shifted in a negative (−) direction.

According to an embodiment of the present disclosure, one end of the first diffusion part 123a, for example, a left end, corresponds to one end of the gate insulating layer 130 and one end of the gate electrode 140, and another end of the first diffusion part 123a, for example, a right end, is located within the inclined surface IS of the buffer groove BG. Similarly, one end of the second diffusion part 123b, for example, a right end, corresponds to another end of the gate insulating layer 130 and another end of the gate electrode 140, and another end of the second diffusion part 123b, for example, a left end, is located within the inclined surface IS of the buffer groove BG. Meanwhile, in the present specification, the meaning of corresponding means being positioned on a straight line or any one plane.

The gate insulating layer 130 is provided on the active layer 120. In this case, the top surface of the gate insulating layer 130 may have a third width W_{GIa} in a horizontal direction, and the third width W_{GIa} may be smaller than the first length L_{ACT} of the active layer 120.

The gate insulating layer 130 is etched using the gate electrode 140 as a mask, and thus may be formed to have the same size as the gate electrode 140. However, the present disclosure is not limited thereto.

One end of the gate insulating layer 130, for example, a left end, may correspond to one end of the gate electrode 140, and another end of the gate insulating layer 130, for example, a right end, may correspond to another end of the gate electrode 140. Accordingly, the third width W_{GIa} of the gate insulating layer 130 may be equal to the second width W_{GE} of the gate electrode 140.

The gate insulating layer 130 may be provided to be stepped on the buffer groove BG. Specifically, the height of the central portion of the gate insulating layer 130 may be lower than the height of the edge portion.

The gate insulating layer 130 may include a silicon nitride layer SiNₓ or a silicon oxide layer SiOₓ, but is not limited thereto. The gate insulating layer 130 may be formed of a single layer or a plurality of layers including an inorganic insulating material and/or an organic insulating material.

The gate electrode 140 is provided on the gate insulating layer 130. A width of the gate electrode 140 in the horizontal direction is provided to be longer than a width of the bottom surface BS of the buffer groove BG in the horizontal direction, and is provided to be smaller than a width of the entire buffer groove BG.

The gate electrode 140 overlaps the buffer groove BG. Specifically, one end and another end of the gate electrode 140 are formed to overlap the inclined surface IS of the buffer groove BG.

According to an embodiment of the present disclosure, one end and another end of the gate electrode 140 overlap the inclined surface IS of the buffer groove BG, respectively, so that the channel part 121 of the active layer 120 may be provided in the buffer groove BG. That is, the channel part 121 is formed as a short channel to enhance the on-current characteristics of the thin film transistor substrate according to an embodiment of the present disclosure, and further, to prevent the channel part 121 from being too short, so that the threshold voltage Vth of the thin film transistor substrate according to an embodiment of the present disclosure is not shifted in the negative (−) direction.

The gate electrode 140 may be stepped on the buffer groove BG. Specifically, the height of the central portion of the gate electrode 140 may be lower than the height of the edge portion. In this case, the height of the gate electrode 140 may be defined as a height from the upper surface of the substrate 100 to the upper surface of the central portion of the gate electrode 140 or a height from the upper surface of the substrate 100 to the upper surface of the edge portion of the gate electrode 140.

The gate electrode 140 may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti). The gate electrode 140 may have a structure including one metal layer or a multilayer structure including at least two metal layers each having different physical properties.

The interlayer insulating layer 150 insulates between the gate electrode 140 and the source electrode 161 and further insulates between the gate electrode 140 and the drain electrode 162. The interlayer insulating layer 150 may be formed of a single layer or a plurality of layers including an inorganic insulating material and/or an organic insulating material.

A first contact hole CH1 and a second contact hole CH2 may be provided in the interlayer insulating layer 150. Accordingly, a portion of the upper surface of the first connection part 122a of the active layer 120 may be exposed by the first contact hole CH1, and further, a portion of the upper surface of the second connection part 122b of the active layer 120 may be exposed by the second contact hole CH2.

The source electrode 161 and the drain electrode 162 may be disposed on the interlayer insulating layer 150.

The source electrode 161 may be electrically connected to the first connection part 122a of the active layer 120 by the first contact hole CH1, and the drain electrode 162 may be electrically connected to the second connection part 122b of the active layer 120 by the second contact hole CH2.

The source electrode 161 and the drain electrode 162 may be formed of the same material as the gate electrode 140, but are not limited thereto and may be formed of a material according to knowledge of the art.

FIG. 2B is a cross-sectional view of a thin film transistor substrate according to another embodiment of the present disclosure. In this case, FIG. 2B corresponds to the cross-sectional view I-I′ of FIG. 1. Meanwhile, an embodiment of FIG. 2B is the same as FIG. 2A except for the configuration of the channel part and the diffusion part, and thus different configurations will be mainly described below.

As shown in FIG. 2B, a thin film transistor substrate according to another embodiment of the present disclosure may include a substrate 100, a buffer layer 110, an active layer 120, a gate insulating layer 130, a gate electrode 140, an interlayer insulating layer 150, a source electrode 161, and a drain electrode 162. Meanwhile, in the embodiment of FIG. 2B, the first height H1 of the bottom surface BS of the buffer groove BG is the same as the embodiment of FIG. 2A, but the upper surface US of the buffer layer 110 has a third height H3 from the bottom surface BS of the buffer layer 110, unlike the embodiment of FIG. 2A. Therefore, the inclined surface IS of the buffer groove BG may be formed at a second angle θ2 different from the first angle θ1.

According to another embodiment of the present disclosure, the channel part 121 of the active layer 120 may not be provided on the inclined surface IS of the buffer groove BG, but may be formed only on the bottom surface BS of the buffer groove BG. Specifically, one end and another end of the channel part 121, for example, both a left end and a right end, may be provided on the bottom surface BS of the buffer groove BG, and neither one end nor another end of the channel part 121 may be provided on the inclined surface IS of the buffer groove BG.

Furthermore, the first diffusion part 123a and the second diffusion part 123b may be formed to cover the entire inclined surface IS of the buffer groove BG. In this case, the first diffusion part 123a and the second diffusion part 123b may be in contact with the channel part 121 at a boundary between the bottom surface BS of the buffer groove BG and the inclined surface IS of the buffer groove BG. Specifically, one end of the first diffusion part 123a, for example, a right end, may be in contact with one end of the channel part 121, for example, at a boundary between the bottom surface BS and the inclined surface IS, and similarly, one end of the second diffusion part 123b, for example, a left end, may be in contact with another end of the channel part 121, for example, at a boundary between the bottom surface BS and the inclined surface IS.

According to another embodiment of the present disclosure, since oxygen vacancy diffused from the first connection part 122a and the second connection part 122b does not reach a portion of the active layer 120 disposed on the bottom surface BS of the buffer groove BG, the length of the channel part 121 provided on the bottom surface BS of the buffer groove BG may not be excessively shortened. Furthermore, since the length of the channel part 121 is not too short, the thin film transistor substrate having a short channel may be implemented without a negative shift of the threshold voltage Vth in the negative (−) direction.

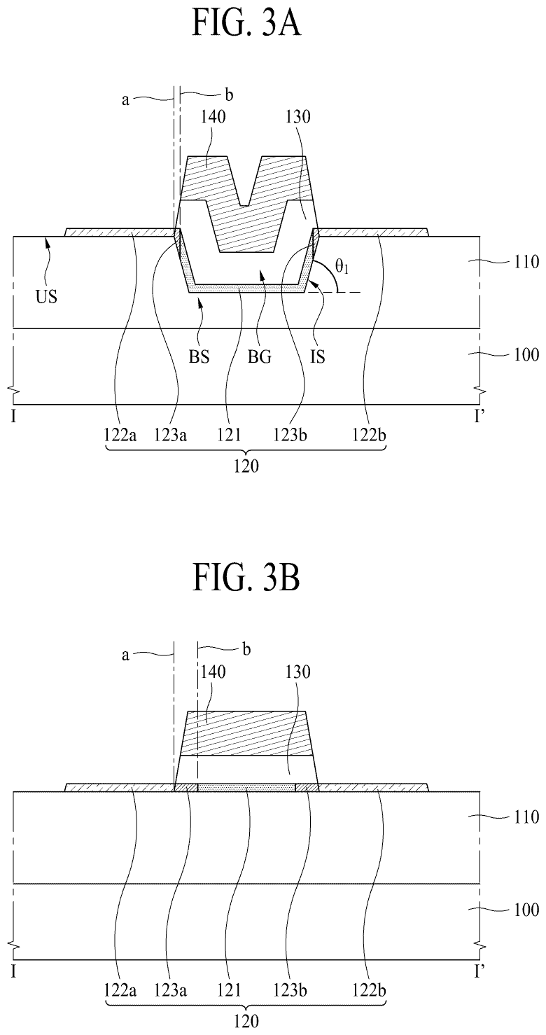

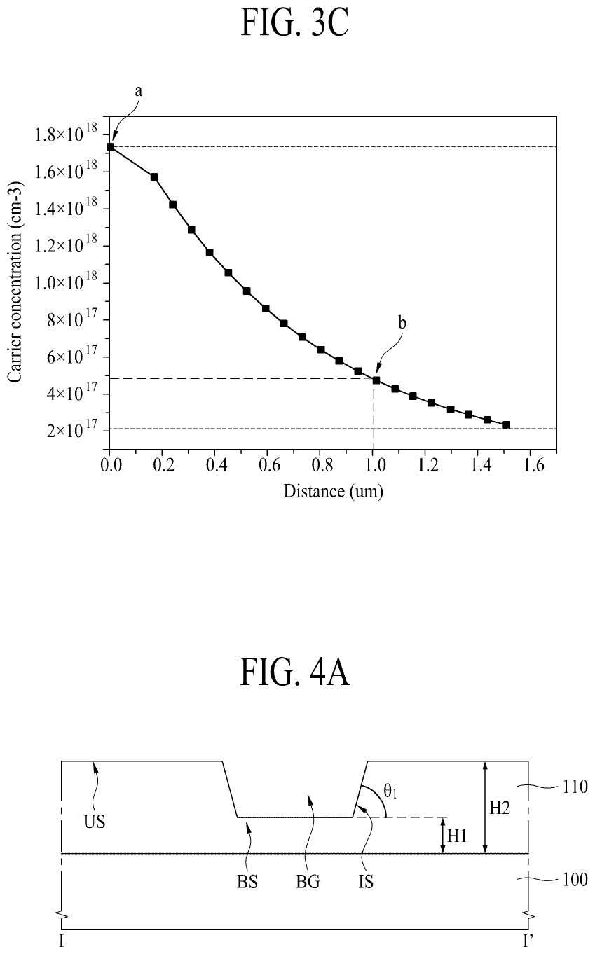

FIGS. 3A and 3B are schematic diagrams illustrating a cross section of a thin film transistor substrate according to an embodiment of the present disclosure and a thin film transistor substrate according to a comparative example, respectively. FIGS. 3A and 3B are cross-sectional views illustrating only a substrate, a buffer layer, an active layer, a gate insulating layer, and a gate electrode for convenience of description of the thin film transistor substrate according to an embodiment of FIG. 2A or the thin film transistor substrate according to a comparative example.

First, since the thin film transistor substrate of FIG. 3A is the same as the thin film transistor substrate of FIG. 2A, repeated description thereof will be omitted. Furthermore, since the thin film transistor substrate according to the comparative example of FIG. 3B has the same configuration except for the configuration of the buffer groove, the remaining configuration will be described by using the same reference numerals, and repeated description thereof will be omitted.

The thin film transistor substrate according to the comparative example includes a substrate 100, a buffer layer 110, an active layer 120, a gate insulating layer 130, and a gate electrode 140, as shown in FIG. 3B. However, a separate buffer groove is not provided in the buffer layer 110 of the thin film transistor substrate according to the comparative example.

FIG. 3C is a graph of a carrier concentration with respect to a distance to a diffusion part of a thin film transistor substrate according to an embodiment and a comparative example of the present disclosure. In this case, FIG. 3C relates to a graph of a carrier concentration with respect to a distance to a thin film transistor substrate according to an embodiment of FIG. 3A and a comparative example of FIG. 3B, each including an active layer having a length of 20 μm and a width of 10 μm (20 μm×10 μm). Also, the distance refers to a distance measured in a direction to the channel part 121 along the active layer 120 from one end of the first connection part 122a.

Point a of FIG. 3C relates to a carrier concentration at one end, for example, the left end, of the thin film transistor substrate according to the embodiment of FIG. 3A and the comparative example of FIG. 3B, and point b of FIG. 3C relates to a carrier concentration at another end, for example, the right end, of the thin film transistor substrate according to the embodiment of FIG. 3A and the comparative example of FIG. 3B.

As can be seen from FIG. 3C, at point a, it can be seen that the carrier concentration is relatively high because one end of the first diffusion part 123a is in contact with the first connection part 122a. On the other hand, at point b, another end of the first diffusion part 123a is spaced apart from the first connection part 122a. In this case, it can be seen that the carrier concentration gradually decreases as it faces the point b from the point a. On the other hand, it can be seen that the carrier concentration at point b differs by approximately 0.28 times compared to the carrier concentration at point a. Accordingly, since the diffusion of oxygen vacancy is significantly reduced from a point spaced about 1 μm from the first connection part 122a, for example, point b, the carrier concentration is relatively low, it may function as the channel part 121 from the point b.

With reference to FIG. 3A, since the first diffusion part 123a is provided on the inclined surface IS, oxygen vacancy from the first connection part 122a is diffused only from the point a to the point b. In this case, since one end of the first diffusion part 123a, for example, a right end thereof is diffused only to the point (point b) corresponding to the gate electrode 140, a length of the channel part 121 as designed may be secured without being too short.

On the other hand, with reference FIG. 3B, since the comparative example according to FIG. 3B does not include a separate buffer groove BG, the first diffusion part 123a is provided on a plane. Accordingly, when oxygen vacancy spreads from point a to point b from the first connection part 122a, one end of the first diffusion part 123a, for example, the right end, is located inside the gate electrode 140, unlike the case of FIG. 3A. Accordingly, a width of the channel part 121 in the horizontal direction is formed to be shorter than a width of the gate electrode 140 in the horizontal direction. As a result, according to the comparative example of FIG. 3B, the channel part 121 having a shorter length than designed is obtained.

As a result, as in the embodiment of FIG. 3A, when the buffer layer 110 is provided with a buffer groove BG and the active layer 120 is provided on the buffer groove BG, the first diffusion part 123a and the second diffusion part 123b are provided on the inclined surface IS of the buffer groove BG so that the length of the channel part 121 can be secured by the designed length.

Meanwhile, in FIGS. 3A to 3C, the carrier concentration according to the distance has been described, focusing on the case where the length of the active layer 120 is 20 μm and the width is 10 μm, but the length and width of the active layer 120 are not limited thereto, and may be formed in various sizes according to knowledge in the art.

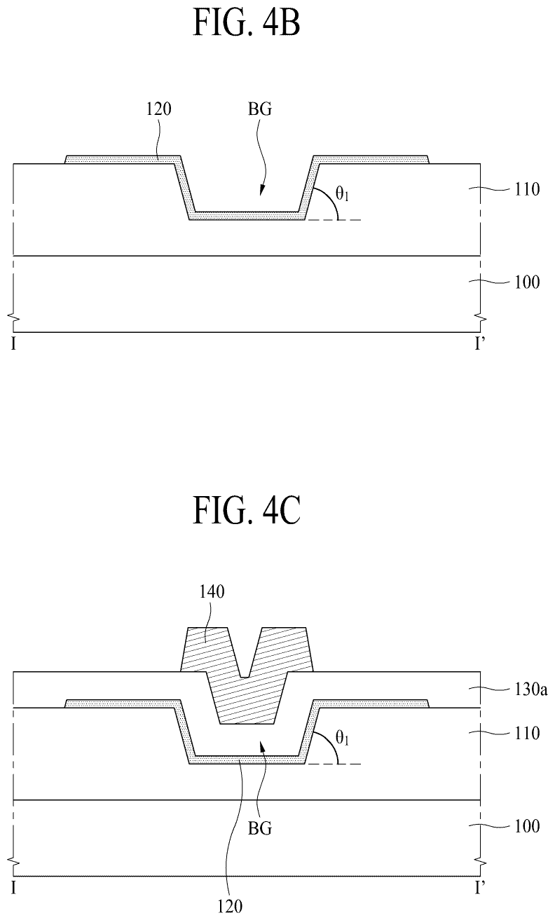

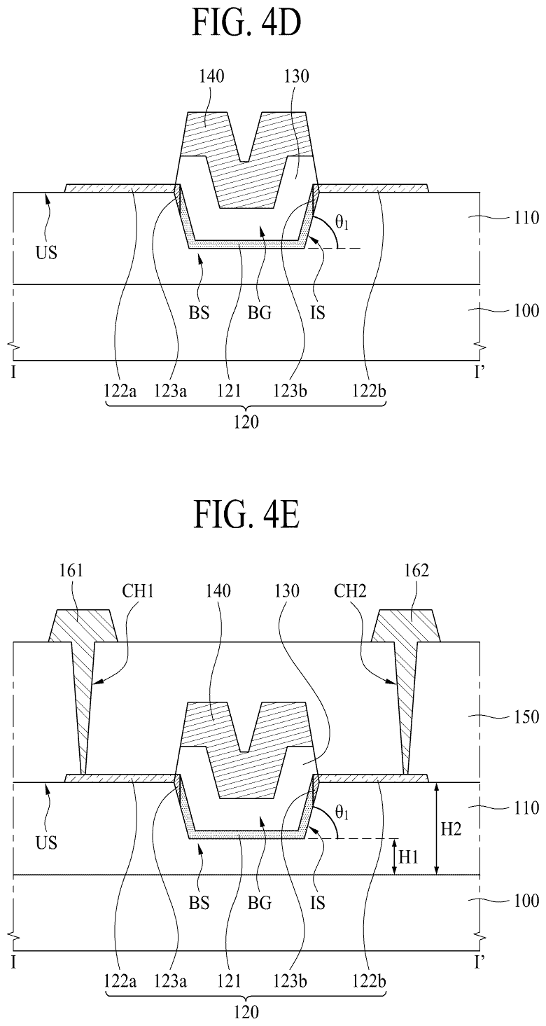

FIGS. 4A to 4E are cross-sectional views of a process of manufacturing a thin film transistor substrate according to an embodiment of the present disclosure. Meanwhile, process cross-sectional views of FIGS. 4A to 4E relate to a process of manufacturing an embodiment of FIG. 2A, and the same reference numerals are assigned to the same configuration, and repeated descriptions will be omitted.

First, as shown in FIG. 4A, a substrate 100 is prepared, and a buffer layer 110 is formed on the substrate 100. Afterwards, a buffer groove BG is formed in the buffer layer 110. In this case, the buffer groove BG is formed such that the bottom surface BS and the inclined surface IS of the buffer groove BG form a first angle θ₁.

Next, as illustrated in FIG. 4B, an active layer 120 is formed on the buffer layer 110. In this case, the active layer 120 may be formed to cover all of the buffer groove BG. Thus, the active layer 120 may cover the bottom surface BS and the inclined surface IS of the buffer groove BG, and a portion of the upper surface US of the buffer layer 110.

Since the active layer 120 is formed to cover the buffer groove BG and a portion of the upper surface US of the buffer layer 110, the active layer 120 may be provided to be stepped on the buffer layer 110.

Next, as illustrated in FIG. 4C, a gate insulating film layer 130a is formed on the buffer layer 110 and the active layer 120, and a gate electrode 140 is patterned on the gate insulating film layer 130a. In this case, the gate insulating film layer 130a may be formed on the entire surface of the substrate 100.

Since the gate insulating film layer 130a and the gate electrode 140 are formed to overlap the buffer groove BG, the gate insulating film layer 130a and the gate electrode 140 are formed so that the height of the central portion is stepped lower than the height of the edge portion.

With respect to the gate electrode 140, although not shown in detail, a metal material layer for forming the gate electrode 140 is deposited on the entire surface of the substrate 100, and then the metal material layer is patterned according to the design to form the gate electrode 140. Meanwhile, the present disclosure is not limited thereto.

Next, as may be seen in FIG. 4D, the gate insulating film layer 130a may be patterned to form the gate insulating layer 130 by using the gate electrode 140 as a mask. In this case, dry etching may be used to form a pattern of the gate insulating layer 130. However, the present disclosure is not limited thereto, and various methods may be used according to the level of those skilled in the art widely known in the art.

Furthermore, in the process of forming the gate insulating layer 130, a portion of the active layer 120, for example, a portion covered by the gate insulating film layer 130a and then exposed while being etched, may be exposed to plasma applied during the etching process. In this case, since a portion of the active layer 120 is made of an oxide semiconductor material, oxygen vacancy is generated and conductive characteristics are provided. As a result, a portion of the active layer 120 covered by the gate insulating film layer 130a and then exposed while being etched becomes the first connection part 122a and the second connection part 122b.

In addition, another portion of the active layer 120 covered with the gate insulating layer 130 may be conductive as oxygen vacancy formed in the first connection portion 122a and/or the second connection portion 122b is diffused in the direction of the channel portion 121. Another portion of the conductive active layer 120 becomes the first diffusion portion 123a and the second diffusion portion 123b.

Finally, as illustrated in FIG. 4E, an interlayer insulating layer 150 is formed to cover the buffer layer 110, the active layer 120, the gate insulating layer 130, and the gate electrode 140. In this case, a first contact hole CH1 and a second contact hole CH2 are provided in the interlayer insulating layer 150 to expose a portion of the upper surface of the first connection part 122a and a portion of the upper surface of the second connection part 122b, respectively, and when the source electrode 161 and the drain electrode 162 are formed on the interlayer insulating layer 150, the source electrode 161 is electrically connected to the first connection part 122a through the first contact hole CH1, and the drain electrode 162 is electrically connected to the second connection part 122b through the second contact hole CH2.

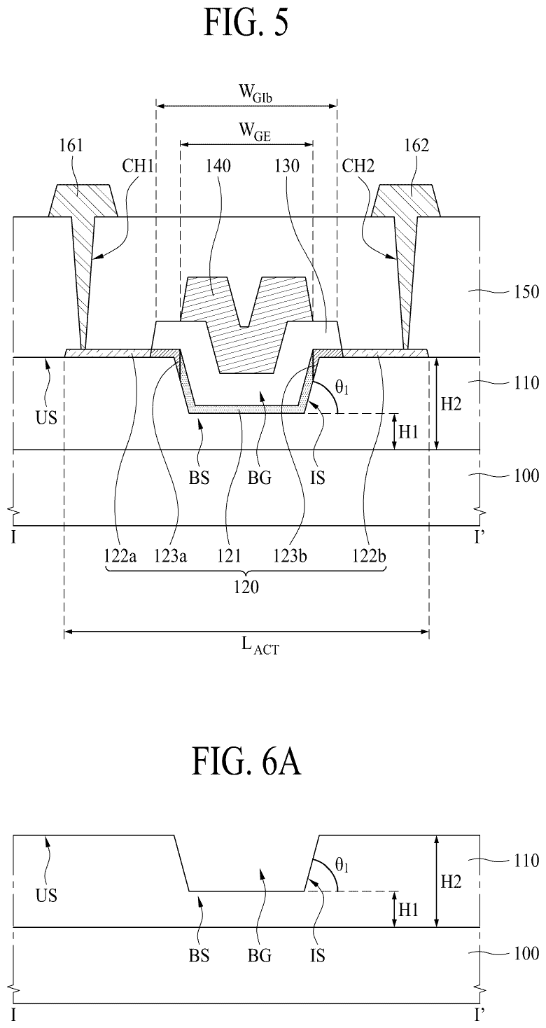

FIG. 5 is a cross-sectional view of a thin film transistor substrate according to another embodiment of the present disclosure. In this case, FIG. 5 corresponds to the cross-sectional view I-I′ of FIG. 1. Meanwhile, an embodiment of FIG. 5 is the same as an embodiment of FIG. 2A except for the configuration of the gate insulating layer, and thus repeated description thereof will be omitted.

As shown in FIG. 5, a thin film transistor substrate according to another embodiment of the present disclosure includes a substrate 100, a buffer layer 110, an active layer 120, a gate insulating layer 130, a gate electrode 140, an interlayer insulating layer 150, a source electrode 161, and a drain electrode 162.

According to another embodiment of the present disclosure, the gate insulating layer 130 is formed to have a size larger than that of the gate electrode 140. Specifically, the upper surface of the gate insulating layer 130 may have a fourth width WGIb in a horizontal direction, and the fourth width WGIb of the gate insulating layer 130 may be shorter than the first length L_{ACT} of the active layer 120 and larger than the second width W_{GE} of the gate electrode 140. Accordingly, one end and another end of the gate insulating layer 130 are provided outside the gate electrode 140 without corresponding to one end and another end of the gate electrode 140.

Since the gate insulating layer 130 is formed larger than the gate electrode 140, a portion of the upper surface of the gate insulating layer 130 may be exposed to the outside without being covered by the gate electrode 140.

The gate insulating layer 130 overlaps a portion of the upper surface US of the buffer groove BG and the buffer layer 110. The gate insulating layer 130 may be provided on the buffer groove BG, and one end, for example, a left end and another end, for example, a right end, may be provided on the upper surface US of the buffer layer 110, respectively.

In this case, one end of the gate insulating layer 130 may be disposed between one end of the gate electrode 140 and one end of the active layer 120, and another end of the gate insulating layer 130 may be disposed between another end of the gate electrode 140 and another end of the active layer 120.

According to another embodiment of the present disclosure, the first diffusion part 123a and the second diffusion part 123b may be provided under the gate insulating layer 130. In detail, the first diffusion part 123a and the second diffusion part 123b may be provided under a portion of the gate insulating layer 130 that is not covered by the gate electrode 140.

Furthermore, the first diffusion part 123a and the second diffusion part 123b may be formed over a region from the upper surface US of the buffer layer 110 to the inclined surface IS of the buffer groove BG. Accordingly, one end of the first diffusion part 123a, for example, a left end and one end of the second diffusion part 123a, for example, a right end, are provided on the upper surface US of the buffer layer 110, and another end of the first diffusion part 123a, for example, the right end and another end of the second diffusion part 123b, for example, the left end, are provided on the inclined surface IS of the buffer groove BG.

By forming in this way, since the length from the first connection part 122a and the second connection part 122b toward the channel part 121 is increased, the length of the channel part 121 as designed may be secured even if oxygen vacancy is diffused from the first connection part 122a or the second connection part 122b in the direction of the channel part 121. As a result, since the length of the channel part 121 may be secured as designed, a thin film transistor substrate having a short channel may be implemented without shifting the threshold voltage Vth in the negative (−) direction.

Meanwhile, although not specifically illustrated in FIG. 5, in another embodiment of the present disclosure, the gate insulating layer 130 is formed larger than the gate electrode 140 such that a portion of the upper surface of the gate insulating layer 130 is exposed to the outside without being covered by the gate electrode 140. Furthermore, as in the embodiment of FIG. 2B described above, oxygen vacancy diffused from the first connection part 122a and the second connection part 122b reaches the inclined surface IS of the buffer groove BG, such that the first diffusion part 123a and the second diffusion part 123b are formed to cover the entire inclined surface IS of the buffer groove BG, and the channel part 121 may be provided only on the bottom surface BS of the buffer groove BG.

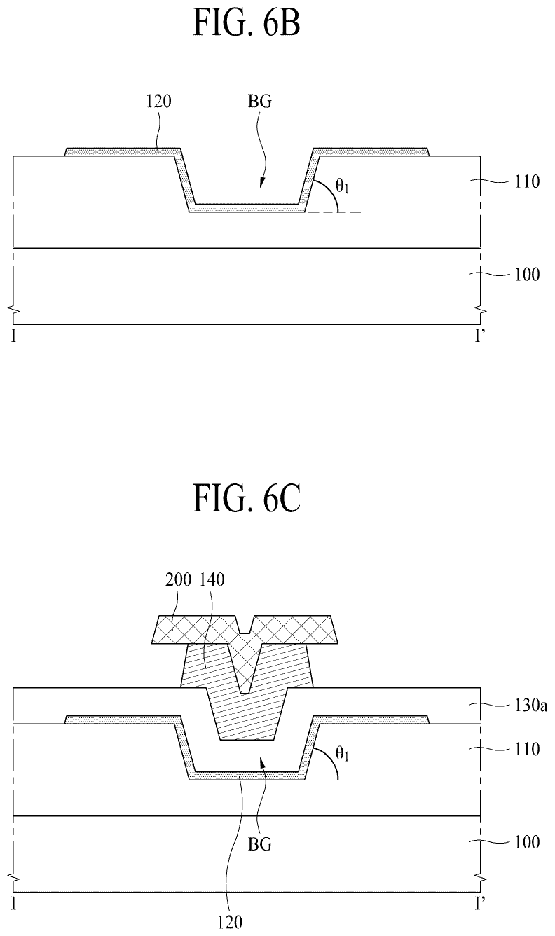

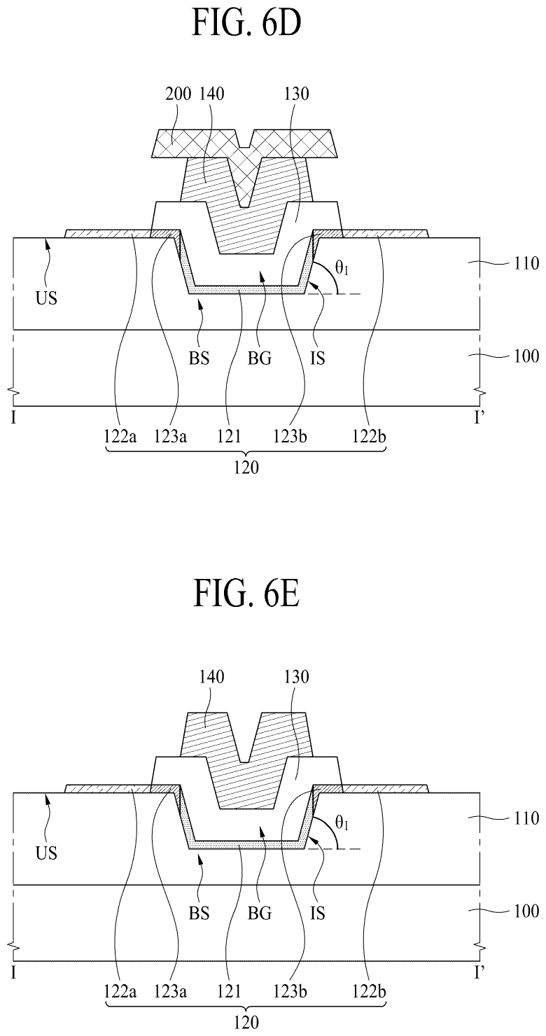

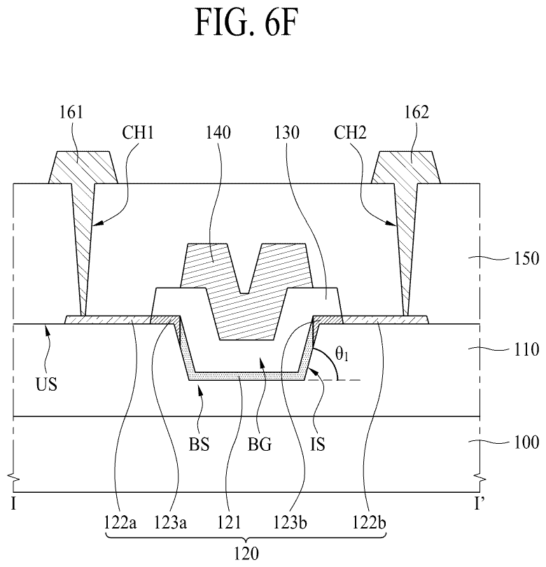

FIGS. 6A to 6F are cross-sectional views of a process of manufacturing a thin film transistor substrate according to another embodiment of the present disclosure. Meanwhile, process cross-sectional views of FIGS. 6A to 6F relate to a process of manufacturing an embodiment of FIG. 5, and the same reference numerals are assigned to the same configuration, and repeated descriptions are omitted.

First, as shown in FIG. 6A, a substrate 100 is prepared, and a buffer layer 110 is formed on the substrate 100, and then a buffer groove BG is formed in the buffer layer 110. Meanwhile, since the manufacturing process of FIG. 6A is the same as the manufacturing process of FIG. 4A, repeated description thereof is omitted.

Next, as shown in FIG. 6B, an active layer 120 is formed on the buffer layer 110. Meanwhile, since the manufacturing process of FIG. 6B is the same as the manufacturing process of FIG. 4B, repeated description thereof is omitted.

Next, as illustrated in FIG. 6C, a gate insulating film layer 130a is formed on the buffer layer 110 and the active layer 120, and a gate electrode 140 is patterned on the gate insulating film layer 130a. In this case, the gate insulating film layer 130a may be formed on the entire surface of the substrate 100.

A resist pattern 200 used to pattern the gate electrode 140 is formed on the gate electrode 140. The gate electrode 140 is patterned using the resist pattern 200 as a mask.

The resist pattern 200 may be formed to have a width wider than that of the gate electrode 140 in the first direction. Furthermore, the resist pattern 200 may be formed to have a width wider than that of the buffer groove BG in the first direction.

Since the gate insulating film layer 130a and the gate electrode 140 are formed to overlap the buffer groove BG, the gate insulating film layer 130a and the gate electrode 140 are formed so that the height of the central portion is stepped lower than the height of the edge portion.

Next, as may be seen in FIG. 6D, the gate insulating film layer 130a may be patterned to form the gate insulating layer 130 by using the resist pattern 200 as a mask. In this case, dry etching may be used to form the gate insulating layer 130 pattern. However, the present disclosure is not limited thereto, and various methods may be used according to the level of those skilled in the art widely known in the art.

According to another embodiment of the present disclosure, since the gate insulating layer 130 is formed using the resist pattern 200 as a mask, the gate insulating layer 130 may be formed to have a larger width than the gate electrode 140. Therefore, one end and another end of the gate insulating layer 130 are provided outside the gate electrode 140 and are formed on the upper surface US of the buffer layer 110.

In the process of forming the gate insulating layer 130, a portion of the active layer 120, for example, a portion covered by the gate insulating film layer 130a and then exposed while being etched, may be exposed to plasma applied during the etching process. In this case, since a portion of the active layer 120 is made of an oxide semiconductor material, oxygen vacancy is generated and conductive characteristics are provided. As a result, a portion of the active layer 120 covered by the gate insulating film layer 130a and exposed while being etched becomes the first connection part 122a and the second connection part 122b.

In addition, another portion of the active layer 120 covered with the gate insulating layer 130 may be conductive as oxygen vacancy formed in the first connection portion 122a and/or the second connection portion 122b is diffused in the direction of the channel portion 121. Another portion of the conductive active layer 120 becomes the first diffusion portion 123a and the second diffusion portion 123b.

According to another embodiment of the present disclosure, since the gate insulating layer 130 is provided on the upper surface US of the buffer layer 110, the first diffusion part 123a and the second diffusion part 123b may also be provided on the upper surface US of the buffer layer 110. By forming in this way, the distance from the first connection part 122a or the second connection part 122b to the direction of the channel part 121 is increased, and thus the length of the channel part 121 as designed may be secured.

Next, as shown in FIG. 6E, the resist pattern 200 may be removed through a stripping process.

Finally, as shown in FIG. 6F, the interlayer insulating layer 150, the source electrode 161, and the drain electrode 162 are formed. Meanwhile, since the manufacturing process of FIG. 6F is the same as the manufacturing process of FIG. 4E, repeated description thereof is omitted.

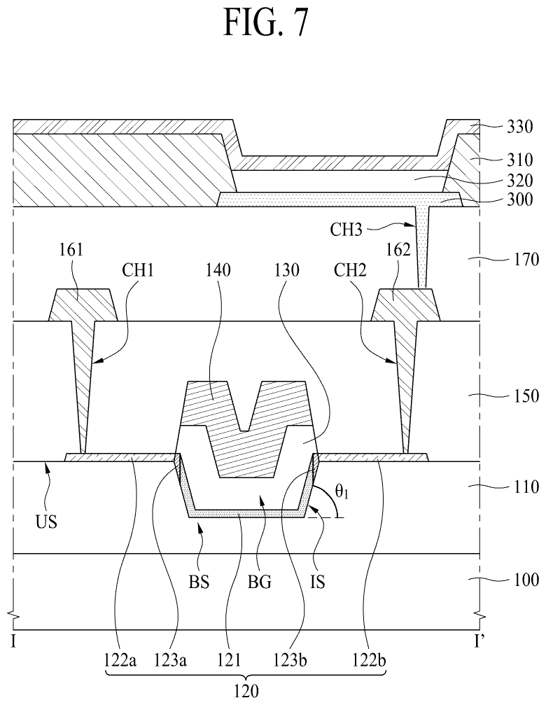

FIG. 7 is a cross-sectional view of a display device including a thin film transistor substrate according to an embodiment of the present disclosure.

As shown in FIG. 7, a display device according to an embodiment of the present disclosure may a substrate 100, a buffer layer 110, an active layer 120, a gate insulating layer 130, a gate electrode 140, an interlayer insulating layer 150, a source electrode 161, a drain electrode 162, a planarization layer 170, a first electrode 300, a bank layer 310, a light emitting layer 320, and a second electrode 330.

Since the substrate 100, the buffer layer 110, the active layer 120, the gate insulating layer 130, the gate electrode 140, the interlayer insulating layer 150, the source electrode 161, and the drain electrode 162 are the same as those in the above-described embodiments, only different configurations will be described below.

The planarization layer 170 is disposed on the source electrode 161 and the drain electrode 162. A third contact hole CH3 is provided in the planarization layer 170, and the drain electrode 162 is exposed by the third contact hole CH3. However, in some cases, the source electrode 161 may be exposed by the third contact hole CH3.

The first electrode 300 is formed on the planarization layer 170, and is connected to the source electrode 161 or the drain electrode 162 through the third contact hole CH3. The first electrode 300 may function as an anode.

The bank layer 310 may be provided to cover an edge of the first electrode 300 to define a light emitting area. Accordingly, an upper surface area of the first electrode 300 exposed without being covered by the bank layer 310 becomes a light emitting area.

The light emitting layer 320 may be provided on the first electrode 300. The light emitting layer 320 may include red, green, and blue light emitting layers patterned for each pixel, or may be formed of a white light emitting layer connected from all pixels. When the light emitting layer 320 is formed of a white emission layer, the light emitting layer 320 may include, for example, a first stack including a blue emission layer, a second stack including a yellow green emission layer, and a charge generation layer provided between the first stack and the second stack, but is not limited thereto.

The second electrode 330 may be provided on the light emitting layer 320. The second electrode 330 may function as a cathode.

Although not shown, an encapsulation layer for preventing moisture or oxygen from penetrating may be additionally formed on the second electrode 330.

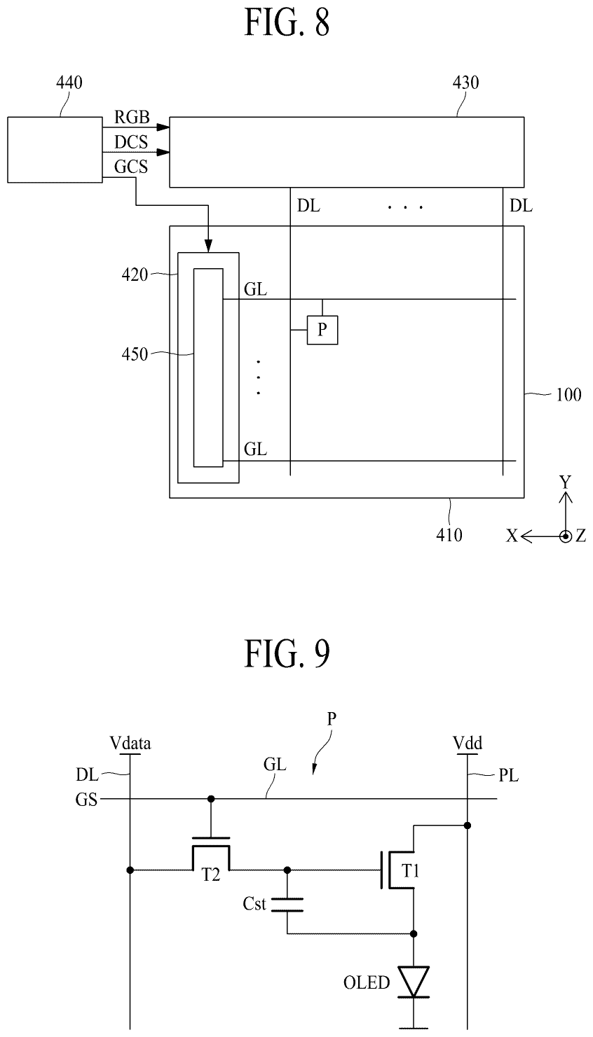

FIG. 8 is a schematic view of a display device according to an embodiment of the present disclosure.

As shown in FIG. 8, a display device according to an embodiment of the present disclosure may include a display panel 410, a gate driver 420, a data driver 430, and a controller 440.

The display panel 410 includes gate lines GLs and data lines DLs, and pixels P are disposed in respective crossing areas of the gate lines GLs and data lines DLs. An image is displayed by driving the pixel P. The gate lines GLs, the data lines DLs, and the pixels P may be disposed on the substrate 100.

The controller 440 controls the gate driver 420 and the data driver 430. The controller 440 outputs a gate control signal GCS for controlling the gate driver 420 and a data control signal DCS for controlling the data driver 430 by using a signal supplied from an external system (not shown). Also, the controller 440 samples input video data input from the external system and rearranges the sampled input video data, and supplies the rearranged digital video data RGB to the data driver 430.

The gate control signal GCS includes a gate start pulse GSP, a gate shift clock GSC, a gate output enable signal GOE, a start signal Vst, and a gate clock GCLK. Further, control signals for controlling a shift register may be included in the gate control signal GCS.

The data control signal DCS includes a source start pulse SSP, a source shift clock signal SSC, a source output enable signal SOE, and a polarity control signal POL.

The data driver 430 supplies a data voltage to the data lines DL of the display panel 410. Specifically, the data driver 430 converts the video data RGB inputted from the controller 440 into an analog data voltage and supplies the data voltage to the data lines DL.

The gate driver 420 may be mounted on the display panel 410. As described above, a structure in which the gate driver 420 is directly mounted on the display panel 410 is referred to as a gate in panel (GIP) structure. Specifically, in the gate-in-panel (GIP) structure, the gate driver 420 may be disposed on the substrate 100.

The gate driver 420 may include a shift register 350.

The shift register 350 sequentially supplies gate pulses to the gate lines GL during one frame by the use of start signal and gate clock transmitted from the controller 440. Herein, the one frame refers to a period in which one image is outputted through the display panel 410. The gate pulse has a turn-on voltage capable of turning on a switching device (thin film transistor) disposed in the pixel P.

Also, during the remaining period of one frame, in which the gate pulse is not supplied, the shift register 350 supplies a gate-off signal capable of turning off the switching device to the gate line GL. Hereinafter, the gate pulse and the gate-off signal are totally referred to as a scan signal GS.

FIG. 9 is a circuit diagram of a pixel included in a display device according to an embodiment of the present disclosure.

As shown in FIG. 9, the display device according to an embodiment of the present disclosure may include a first thin film transistor T1, a second thin film transistor T2 and a capacitor Cst.

The first thin film transistor T1 is a driving thin film transistor, and the second thin film transistor T2 is a switching thin film transistor. At least one of the first thin film transistor T1 and the second thin film transistor T2 may be formed of the above-described various thin film transistors.

The first thin film transistor T1 is switched according to the data voltage Vdata supplied from the second thin film transistor T2, generates a data current from the driving voltage VDD supplied from the power line PL, and supplies it to the organic light emitting diode OLED.

The second thin film transistor T2 is switched according to the gate signal GS supplied to the gate line GL and supplies the data voltage Vdata supplied from the data line DL to the first thin film transistor T1.

According to an embodiment of the present disclosure, the thin film transistor substrate according to the above-described embodiment may be used as a thin film transistor substrate including any one of the first thin film transistor T1 and the second thin film transistor T2.

The capacitor Cst serves to maintain the data voltage supplied to the first thin film transistor T1 for one frame, and is provided between the gate electrode and the source electrode of the first thin film transistor T1.

The organic light emitting diode OLED emits predetermined light according to a data current supplied from the first thin film transistor T1.

Accordingly, the present disclosure may have the following advantages.

According to an embodiment of the present disclosure, both ends of the gate electrode are overlapped with the inclined surfaces of the buffer groove provided in the buffer layer, and the channel part of the active layer is disposed inside the buffer groove, that is, the channel part is formed to have a short length, thereby improving the on-current characteristics of the thin film transistor substrate according to an embodiment of the present disclosure.

Furthermore, according to an embodiment of present disclosure, by providing an active layer on the inclined surface of the buffer groove, the length of the channel part is not too short during the conducting process, so that the threshold voltage Vth of the thin film transistor substrate according to an embodiment of present disclosure is not shifted in the negative (−) direction.

It will be apparent to those skilled in the art that various substitutions, modifications, and variations are possible within the scope of the present disclosure without departing from the spirit and scope of the present disclosure. Therefore, the scope of the present disclosure includes the following claims, and all changes or modifications derived from the meaning, range and equivalent concept of the claims should be interpreted as being included in the scope of the present disclosure.

What is claimed is:

1. A thin film transistor substrate comprising:
a substrate;
a buffer layer having a buffer groove disposed on the substrate, wherein the buffer groove includes an inclined surface;
an active layer disposed on the buffer layer; and
a gate electrode disposed on the active layer,
wherein the active layer is disposed to be stepped on the buffer groove,
and one end of the gate electrode overlaps the inclined surface of the buffer groove.

2. The thin film transistor substrate according to claim 1,
wherein one end of the gate electrode overlaps a portion of the active layer disposed on the inclined surface of the buffer groove.

3. The thin film transistor substrate according to claim 1, further comprising:
a gate insulating layer disposed between the active layer and the gate electrode,
wherein the gate insulating layer overlaps the buffer groove, and one end of the gate insulating layer corresponds to one end of the gate electrode.

4. The thin film transistor substrate according to claim 1, further comprising:
a gate insulating layer disposed between the active layer and the gate electrode,
wherein the gate insulating layer overlaps the buffer groove, and one end of the gate insulating layer is disposed between one end of the active layer and one end of the gate electrode.

5. The thin film transistor substrate according to claim 4,
wherein the gate insulating layer has a first width, the gate electrode has a second width, the active layer has a first length,
and the first width of the gate insulating layer is larger than the second width of the gate electrode and smaller than the first length of the active layer.

6. The thin film transistor substrate according to claim 1,
wherein the active layer includes a channel part, a connection part disposed on one side of the channel part, and a diffusion part disposed between the channel part and the connection part,
and the channel part includes a first region in contact with a bottom surface of the buffer groove and a second region in contact with the inclined surface of the buffer groove.

7. The thin film transistor substrate according to claim 6,
wherein one end of the second region of the channel part is disposed in the inclined surface.

8. The thin film transistor substrate according to claim 6,
wherein one end of the second region of the channel part corresponds to one end of the gate electrode.

9. The thin film transistor substrate according to claim 6,
wherein one end of the diffusion part is disposed on the inclined surface of the buffer groove.

10. The thin film transistor substrate according to claim 9,
wherein another end of the diffusion part corresponds to one end of the gate electrode.

11. The thin film transistor substrate according to claim 9,
wherein another end of the diffusion part is disposed between one end of the gate electrode and one end of the active layer.

12. The thin film transistor substrate according to claim 1,
wherein the active layer includes a channel part, a connection part disposed on one side of the channel part, and a diffusion part disposed between the channel part and the connection part,
one end of the channel part is disposed on a bottom surface of the buffer groove, and one end of the diffusion part is disposed on the inclined surface of the buffer groove,
and one end of the channel part and one end of the diffusion part are in contact with each other at a boundary between the bottom surface of the buffer groove and the inclined surface of the buffer groove.

13. The thin film transistor substrate according to claim 1,
wherein the buffer groove further includes a bottom surface connected to the inclined surface,
and an angle formed between the bottom surface and the inclined surface is equal to 30 degrees or more and equal to 45 degrees or less.

14. The thin film transistor substrate according to claim 1,
wherein the buffer groove further includes a bottom surface connected to the inclined surface,
and a depth of the bottom surface of the buffer groove is equal to 1.41 μm or more and equal to 2 μm or less.

15. A thin film transistor substrate comprising:
a substrate;
a buffer layer having a buffer groove disposed on the substrate;
an active layer disposed on the buffer layer; and
a gate electrode disposed on the active layer,
wherein the buffer groove includes a bottom surface and an inclined surface connected to the bottom surface,
the active layer includes a channel part, a connection part disposed on one side of the channel part, and a diffusion part disposed between the channel part and the connection part,
and the channel part overlaps the bottom surface and the inclined surface, and one end of the channel part is disposed on the inclined surface of the buffer groove.

16. The thin film transistor substrate according to claim 15,
wherein a width of the bottom surface of the buffer groove is smaller than a width of the gate electrode,
and a width of the entire bottom surface and inclined surface of the buffer groove is larger than the width of the gate electrode.

17. The thin film transistor substrate according to claim 15, further comprising:
a gate insulating layer disposed between the active layer and the gate electrode,
wherein an entire area of the diffusion part overlaps the gate insulating layer.

18. The thin film transistor substrate according to claim 15,
wherein a portion of the diffusion part does not overlap the gate electrode.

19. The thin film transistor substrate according to claim 15,
wherein one end of the channel part corresponds to one end of the gate electrode.

20. A display device including a thin film transistor substrate comprising:
a substrate;
a buffer layer disposed on the substrate and having a buffer groove;
an active layer disposed on the buffer layer; and
a gate electrode disposed on the active layer,
wherein the active layer is disposed to be stepped on the buffer groove,
and one end of the gate electrode overlaps an inclined surface disposed in the buffer groove.
